(19) United States
(12) Patent Application Publication
(10) Pub. No.: US 2026/0190680 A1
(43) Pub. Date: Jul. 2, 2026

(54) DISPLAY APPARATUS

(71) Applicant: LG Display Co., Ltd., Seoul (KR)

(72) Inventors: Choong-Keun YOO, Paju-si (KR); Binn KIM, Paju-si (KR)

(73) Assignee: LG Display Co., Ltd., Seoul (KR)

(21) Appl. No.: 19/397,743

(22) Filed: Nov. 21, 2025

(30) Foreign Application Priority Data
Dec. 26, 2024 (KR) 10-2024-0196878

(51) Int. Cl. H10K 59/126; G09G 3/3233

(52) U.S. Cl. CPC H10K 59/126; G09G 3/3233; G09G 2300/0421; G09G 2300/0842; G09G 2330/02

(57) ABSTRACT

A display apparatus includes a substrate, a light emitting device on the substrate and including a first electrode, a light emitting layer, and a second electrode, a fence disposed along the outer periphery of the first electrode and covering an edge region of an upper surface of the first electrode, and a shielding electrode on the fence and configured to receive a voltage.

### CROSS-REFERENCE TO RELATED APPLICATION

This application claims priority to Korean Patent Application No. 10-2024-0196878, filed in the Republic of Korea on Dec. 26, 2024, the entire contents of which are hereby expressly incorporated by reference into the present application.

### BACKGROUND

### Technical Field

The present disclosure relates to a display apparatus and, more particularly, to the display apparatus having improved light emission characteristics.

### Description of the Related Art

Recently, with the development of multimedia, the importance of display apparatuses is increasing. In response to this, flat panel display apparatuses, such as a liquid crystal display apparatus, a plasma display apparatus, and an organic light emitting display apparatus, are being commercialized. Among these display apparatuses, the organic light emitting display apparatus is currently widely used because of its high response speed, high luminance, and wide viewing angle.

To manufacture a high resolution display apparatus, the gap between sub-pixels typically need to be minimized or reduced. However, in this case, as the gap between adjacent sub-pixels decreases, a lateral leakage current is more likely to be generated between adjacent sub-pixels. This side leakage current may cause unwanted light emission in pixels, which is an important cause of defect in the display apparatus.

### SUMMARY

The present disclosure is directed to a display apparatus that substantially obviates one or more of the problems associated with the limitations and disadvantages of the related art.

An object of the present disclosure is to provide a display apparatus capable of preventing or reducing image quality defects due to mixing of light emitted from adjacent sub-pixels.

Additional features and advantages of the present disclosure are set forth in the description which follows, and will be apparent from the description, or evident by practice of the present disclosure. The objectives and other advantages of the present disclosure can be realized and attained by the features described herein as well as in the appended drawings.

To achieve these and other objects of the present disclosure, as embodied and broadly described herein, a display apparatus according one or more example embodiments of the present disclosure includes a substrate, a light emitting device on the substrate and including a first electrode, a light emitting layer, and a second electrode, a fence disposed along the outer periphery of the first electrode and covering an edge region of an upper surface of the first electrode, and a shielding electrode on the fence and configured to receive a voltage.

In or more example embodiments, the shielding electrode and the second electrode may be configured to receive the same voltage or have a same electric potential.

In or more example embodiments, the substrate may include one of a semiconductor wafer, a plastic material, and a glass.

In or more example embodiments, the display apparatus may further include a transistor on the substrate, a passivation layer covering the transistor, wherein the transistor may be electrically connected to the first electrode through a first contact hole in the passivation layer.

In or more example embodiments, the display apparatus may further include a reflective layer on the passivation layer and a planarization layer covering the reflective layer, with the light emitting device being disposed on the planarization layer.

In or more example embodiments, the shielding electrode may be electrically connected to the reflective layer through a second contact hole in the planarization layer and a third contact hole in the fence.

In or more example embodiments, the display apparatus may further include a connection electrode on the planarization layer, wherein the connection electrode may be electrically connected to the shielding electrode through the third contact hole in the fence and to the reflective layer through the second contact hole in the planarization layer.

In or more example embodiments, the connection electrode may include a same material as the first electrode and be insulated from the first electrode.

In or more example embodiments, the voltage to be supplied to the shielding electrode may be a power supply voltage, and the shielding electrode may be configured to receive the power supply voltage through the reflective layer.

In one or more example embodiments, the power supply voltage may be a low potential voltage.

In one or more example embodiments, the shielding electrode may be connected directly to the reflective layer through the second contact hole and the third contact hole, and the second contact hole and the third contact hole may be aligned to form a continuous contact hole through the planarization layer and the fence.

In one or more example embodiments, the display device may further include a power supply electrode on the passivation layer and electrically connected to the shielding electrode to supply the voltage to the shielding electrode, wherein the voltage is a power supply voltage.

In one or more example embodiments, the power supply electrode may be electrically connected to the shielding electrode through a second contact hole in the planarization layer and a third contact hole in the fence.

In one or more example embodiments, the shielding electrode may be connected directly to the power supply electrode through the second contact hole and the third contact hole, and the second contact hole and the third contact hole may be aligned to form a continuous contact hole through the planarization layer and the fence.

In one or more example embodiments, the power supply electrode may include a same material as the reflective layer and be insulated from the reflective layer.

In one or more example embodiments, the shielding electrode may overlap the edge region of the upper surface of the first electrode, and the fence may include an insulating material and be disposed between the shielding electrode and the edge region of the upper surface of the first electrode.

In one or more example embodiments, the light emitting layer may be disposed on the shielding electrode and the first electrode, and the second electrode may be disposed on the light emitting layer, with the second electrode overlapping the shielding electrode.

In another aspect, a display apparatus according one or more example embodiments of the present disclosure includes a substrate; a transistor on the substrate; a light emitting device over the transistor and including a first electrode electrically connected to the transistor, a light emitting layer, and a second electrode; a fence disposed along an outer periphery of the first electrode and overlapping an edge region of the first electrode, the fence including an insulating material; and a shielding electrode on the fence and overlapping the edge region of the first electrode, the fence being disposed between the shielding electrode and the edge region of the first electrode. The light emitting layer may be disposed on the shielding electrode and the first electrode, and the second electrode may be disposed on the light emitting layer and overlap the shielding electrode. The shielding electrode and the second electrode may be configured to receive a same power supply voltage or be at a same electric potential.

In one or more example embodiments, the display apparatus may further include a reflective layer between the transistor and the first electrode of the light emitting device, wherein the shielding electrode may be electrically connected to the reflective layer and be configured to receive the power supply voltage through the reflective layer.

In one or more example embodiments, the display apparatus may further include a passivation layer on the transistor, a reflective layer on the passivation layer and under the first electrode of the light emitting device, and a power supply electrode on the passivation layer and electrically insulated from the reflective layer. The shielding electrode may be electrically connected to the power supply electrode and be configured to receive the power supply voltage through the power supply electrode.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a schematic block diagram of a display apparatus according to one or more example embodiments of the present disclosure.

FIG. 2 is the schematic block diagram of a sub-pixel according to one or more example embodiments of the present disclosure.

FIG. 3 is a circuit diagram conceptually illustrating an example sub pixel of an organic light emitting display apparatus according to one or more example embodiments of the present disclosure.

FIG. 4 is a cross-sectional view showing a partial structure of an example sub-pixel of a display apparatus according to a first example embodiment of the present disclosure.

FIG. 5A is a cross-sectional view schematically showing a portion of an example sub-pixel of a display apparatus without a shielding electrode.

FIG. 5B is a cross-sectional view schematically showing a portion of an example sub-pixel of a display apparatus with the shielding electrode according to an example embodiment of the present disclosure.

FIG. 6 is a cross-sectional view showing a partial structure of an example sub-pixel of a display apparatus according to a second example embodiment of the present disclosure.

FIG. 7 is a cross-sectional view showing a portion of an example sub-pixel of a display apparatus according to a third example embodiment of the present disclosure.

FIG. 8 is a cross-sectional view showing a portion of an example sub-pixel of a display apparatus according to a fourth example embodiment of the present disclosure.

### DETAILED DESCRIPTION

Advantages and features of the present disclosure and methods for achieving them will be made clear from example embodiments described below in detail with reference to the accompanying drawings. The present disclosure may, however, be implemented in many different forms and should not be construed as being limited to the example embodiments set forth herein. The example embodiments are provided such that this disclosure will be more thorough and complete and will more fully convey the scope of the present disclosure to those skilled in the art to which the present disclosure pertains. A protected scope of the present disclosure may be defined by the scope of the appended claims and their equivalents.

Shapes, sizes, ratios, angles, numbers, and the like disclosed in the drawings for describing the example embodiments of the present disclosure are illustrative, and thus the present disclosure is not limited to the illustrated examples. The same reference numerals refer to the same components throughout this disclosure, unless otherwise specified. Further, in the following description of the present disclosure, where a detailed description of a known related art may unnecessarily obscure a feature or aspect of the present disclosure, the detailed description of such known related art may be omitted herein.

Where terms such as “including,” “having,” “comprising,” and the like are used in this disclosure, other parts may be added unless a more specific term like “only” is used herein. Where a component is expressed as being singular, being plural is included unless otherwise specified.

In analyzing a component, an error range is to be interpreted as being included even where there is no explicit description.

In a description of a positional relationship, for example, where a positional relationship of two parts is described as being “on,” “above,” “below,” “next to,” or the like, one or more other parts may be located between the two parts unless a more specific term like “immediately” or “directly” is used.

In a description of a temporal relationship, for example, where a temporal predecessor relationship is described as being “after,” “subsequent,” “next to,” “prior to,” or the like, cases that are not continuous or consecutive may also be included unless a more specific term like “immediately” or “directly” is used.

Although such terms as first, second, and the like may be used to describe various components, these components are not substantially limited by these terms. These terms are used only to refer to one component separately from another component. Therefore, a first component described below may substantially be a second component, and vice versa, within the technical spirit of the present disclosure.

In describing the components of the disclosure, terms such as first, second, A, B, (a), (b), etc., may be used. These terms are only for referring to the elements separately from other elements, and the essence, order, or number of the elements is not limited by the terms. Where a component is described as being “coupled” or “connected” to another component, the component may be directly or indirectly coupled or connected to the other component, unless a more specific term like “directly” is used. It should be understood that one or more other components may be “interposed” and connected between the components that are “coupled” or “connected” to each other.

As used herein, the term “apparatus” may refer to a display apparatus such as a liquid crystal module (LCM) or an organic light emitting display module (OLED module) that includes a display panel and a driving unit (or a driving circuit) for driving the display panel. Further, the term “apparatus” may refer to a notebook computer, a television, a computer monitor, a vehicle electric apparatus including an apparatus for a vehicle or other type of vehicle, or a set electronic apparatus or a set apparatus, such as a mobile electronic apparatus of a smart phone, an electronic pad, or the like, which is a finished product (a complete product or a final product) including an LCM or an OLED module.

Accordingly, the apparatus in the present disclosure may encompass a display apparatus itself, such as the LCM, the OLED module, etc., and an apparatus for end users like an application product or a set apparatus that includes the LCM, the OLED module, or the like.

Hereinafter, various example embodiments of the present disclosure will be described in detail with reference to the accompanying drawings.

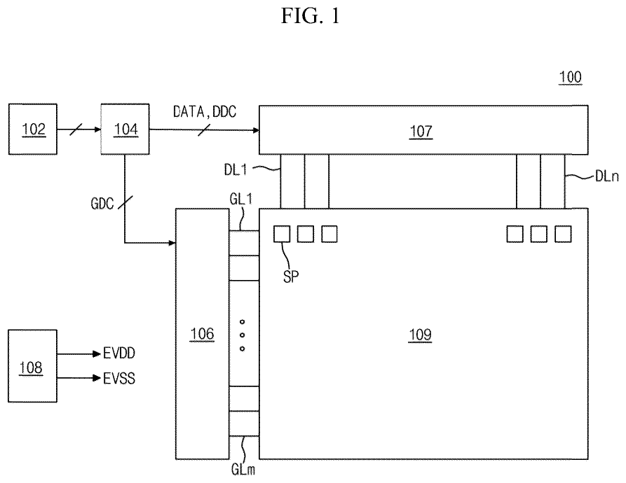

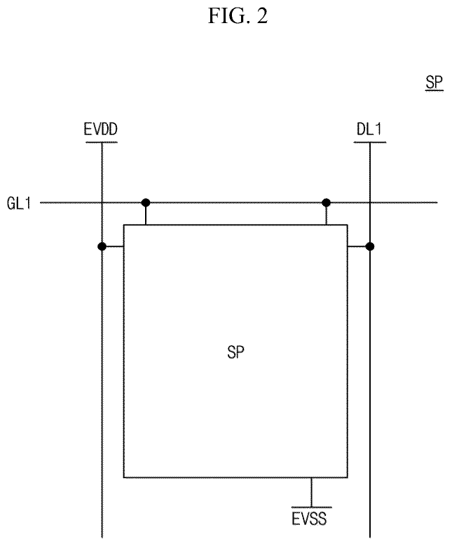

FIG. 1 is a schematic block diagram of a display apparatus according to one or more example embodiments of the present disclosure, and FIG. 2 is the schematic block diagram of a sub-pixel of an organic light emitting display apparatus according to one or more example embodiments of the present disclosure.

As shown in FIG. 1, the example organic light emitting display apparatus 100 includes an image processing unit (or an image processing circuit or image processor) 102, a timing controlling unit (or a timing controller) 104, a gate driving unit (or a gate driving circuit or gate driver) 106, a data driving unit (or a data driving circuit or data driver) 107, a power supplying unit (or a power supply circuit or power supply) 108, and a display panel 109.

The image processing circuit 102 outputs an image data supplied from an external source and a driving signal for driving various devices. For example, the driving signal from the image processing circuit 102 can include a data enable signal, a vertical synchronizing signal, a horizontal synchronizing signal, and a clock signal.

The image data and the driving signal are supplied to the timing controller 104 from the image processing circuit 102. The timing controller 104 writes and outputs gate timing controlling signal GDC for controlling the driving timing of the gate driving circuit 106 and data timing controlling signal DDC for controlling the driving timing of the data driving circuit 107 based on the driving signal from the image processing circuit 102.

The gate driving circuit 106 outputs a scan signal to the display panel 109 in response to the gate timing control signal GDC supplied from the timing controller 104. The gate driving circuit 106 outputs the scan signal through a plurality of gate lines GL1 to GLm. In this case, the gate driving circuit 106 may be formed in the form of an integrated circuit (IC), but is not limited thereto.

The data driving circuit 107 outputs the data voltage to the display panel 109 in response to the data timing control signal DDC input from the timing controller 104. The data driving circuit 107 samples and latches the digital data signal DATA supplied from the timing controller 104 to convert it into an analog data voltage based on the gamma voltage. The data driving circuit 107 outputs the data voltage through the plurality of data lines DL1 to DLn. In this case, the data driving circuit 107 may be mounted on the upper surface of the display panel 109 in the form of an integrated circuit (IC), but is limited thereto.

The power supply circuit 108 outputs and supplies a high potential voltage and a low potential voltage to the display panel 109. The high potential voltage is supplied to the display panel 109 through the first power line EVDD, and the low potential voltage is supplied to the display panel 109 through the second power line EVSS. Here, the voltage from the power supply circuit 108 may be applied to the data driving circuit 107 and/or the gate driving circuit 106 to drive the data driving circuit 107 and/or the gate driving circuit 106.

The display panel 109 displays an image based on the data voltage from the data driving circuit 107, the scan signal from the gate driving circuit 106, and the power from the power supply circuit 108.

The display panel 109 includes a plurality of sub-pixels SP to display the image. The sub-pixels SP can include a Red sub-pixel, a Green sub-pixel, and a Blue sub-pixel. Further, the sub-pixels SP can include a White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the first gate line GL1, the first data line DL1, the first power line EVDD, and the second power line EVSS. The number of transistors and capacitors and a driving method of the sub-pixel SP may be selected according to the configuration of the pixel circuit.

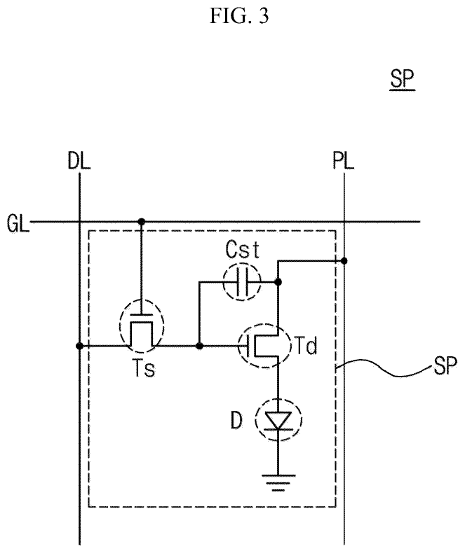

FIG. 3 is the circuit diagram illustrating an example sub-pixel SP of the organic light emitting display apparatus 100 according to one or more example embodiments of the present disclosure.

As shown in FIG. 3, the organic light emitting display apparatus 100 according to example embodiments of the present disclosure includes the gate line GL, the data line DL, and the power line PL crossing each other for defining the sub-pixel SP. A switching thin film transistor Ts, a driving thin film transistor Td, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the example organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, a current proportional to the data signal is supplied to the organic light emitting device D from the power line PL through the driving thin film transistor Td, and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the example sub-pixel configuration of FIG. 3, only two thin film transistors Td and Ts and one capacitor Cst are provided, but the present disclosure is not limited thereto. Three or more thin film transistors and two or more capacitors may be provided in a sub-pixel SP in other embodiments of the present disclosure.

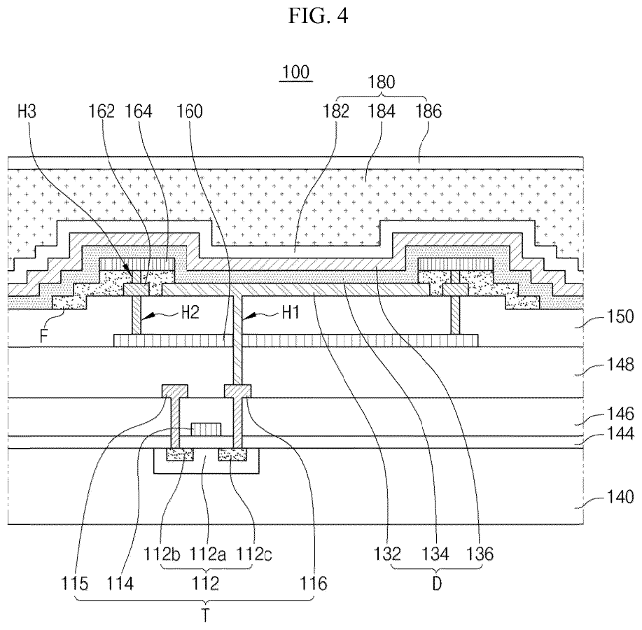

FIG. 4 is a cross-sectional view showing a partial structure of an example sub-pixel of the display apparatus 100 according to the first example embodiment of the present disclosure. In the drawing, only a portion of one sub-pixel SP is shown for convenience of explanation.

As shown in FIG. 4, in the display apparatus 100 according to the first example embodiment of the present disclosure, a transistor T (e.g., a driving thin film transistor Ts) is disposed on a wafer substrate 140.

The wafer substrate 140 may be a single crystal silicon wafer formed by growing single crystal silicon (Si), but is not limited thereto. For example, the wafer substrate 140 may be a wafer made of various semiconductor materials.

The transistor T includes an active region 112 disposed within the wafer substrate 140, a gate insulating layer 144 on the wafer substrate 140, a gate electrode 114 on the gate insulating layer 144, an interlayer insulating layer 146 covering the gate electrode 114, and a source electrode 115 and a drain electrode 116 on the interlayer insulating layer 146.

The active region 112 may be formed inside the wafer substrate 140 (e.g., into a top surface of the wafer substrate 140). The active region 112 may include a central channel region 112a that is not doped with impurities inside the wafer substrate 140, and a source region 112b and a drain region 112c that are disposed respectively at two opposing sides of the channel region 112a and doped with impurities.

The gate insulating layer 144 may be composed of a single layer or multiple layers made of an inorganic material, such as SiOx or SiNx, but is not limited thereto.

The gate electrode 114 may be made of metal. For example, the gate electrode 114 may be formed of the single layer or multiple layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of an organic material, such as photo-acryl, or may formed of a single layer or multiple layers made of an inorganic material, such as SiOx or SiNx, but is not limited thereto. Further, the interlayer insulating layer 146 may be formed of multiple layers of organic and inorganic material layers, but is not limited thereto.

The source electrode 115 and the drain electrode 116 may be formed of a single layer or multiple layers made of one or alloys of molybdenum (Mo), aluminum (Al), chromium (Cr), gold (Au), titanium (Ti), nickel (Ni), neodymium (Nd), and copper (Cu), but are not limited thereto. The source electrode 115 and the drain electrode 116 may respectively contact the source region 112b and the drain region 112c of the active region 112 through respective contact holes formed in the gate insulating layer 144 and the interlayer insulating layer 146.

Although not shown in drawing, a buffer layer may additionally be formed between the wafer substrate 140 and the gate insulating layer 144. The buffer layer enhances adhering force between the wafer substrate 140 and the layers thereon. Further, the buffer layer may block various types of materials, such as alkali components, flowing out from the wafer substrate 140. The buffer layer may be formed of a single layer of SiNx or SiOx, or multiple layers thereof. Where the buffer layer is formed of multiple layers, layers of SiOx and SiNx may be alternately formed.

A passivation layer 148 is formed on the wafer substrate 140 where the transistor T is disposed. The passivation layer 148 may be formed of an organic material such as photo acrylic. But it is not limited thereto. The passivation layer 148 may include a plurality of layers including inorganic and organic layers.

The reflective layer 160 may be formed on the passivation layer 148. The reflective layer 160 may be formed of a metal having good reflectivity, such as Ag or Al, but is not limited thereto. In this case, the reflective layer 160 may be floated so that no signal is applied thereto.

A planarization layer 150 is formed on the passivation layer 148 where the reflective layer 160 is disposed. The planarization layer 150 may be formed of an organic material such as photo acrylic. But it is not limited thereto. The planarization layer 150 may include a plurality of layers including inorganic and organic layers. Furthermore, the planarization layer 150 may be formed of the same material as the passivation layer 148 but may alternatively be formed of a different material from the passivation layer 148.

A light emitting device D is disposed on the planarization layer 150. The light emitting device D includes a first electrode 132, a light emitting layer 134, and a second electrode 136.

The first electrode 132 is disposed on the planarization layer 150 and electrically connected to the drain electrode 116 of the transistor T through a first contact hole H1 formed in the passivation layer 148 and in the planarization layer 150.

Although the first contact hole H1 appears as penetrating the reflective layer 160 in the drawing, this is merely due to the characteristics and limitation of illustrating this cross-sectional view. The first contact hole H1 is formed in the planarization layer 150 in a region where the reflective layer 160 is not formed. Thus, the reflective layer 160 and the first electrode 132 are electrically insulated from each other.

The first electrode 132 may be made of a half-transparent conductive material that transmits light. For example, the first electrode 132 may be made of at least one or more of the alloys such as LiF/Al, CsF/Al, Mg:Ag, Ca/Ag, Ca:Ag, LiF/Mg:Ag, LiF/Ca/Ag, and LiF/Ca:Ag. Alternatively, the first electrode 132 may be formed of a transparent metal oxide material such as indium tin oxide (ITO) or indium zinc oxide (IZO). Where the display apparatus 100 according to example embodiments of the present disclosure is of the top emission type, the first electrode 132 is made of a transparent metal. However, in example embodiments of the present disclosure, the first electrode 132 may be made of a transparent conductive material or a half-transparent conductive material, and the reflective layer 160 may be disposed at the lower portion of the light emitting device D to reflect the light output downward from the light emitting device D upward, thereby improving the light emission efficiency of the light emitting device D. Furthermore, the reflective layer 160 can improve the light extraction efficiency of the light emitting device D by microcavity.

A fence F is formed at the boundary of each sub-pixel on the planarization layer 150. The fence F may be formed to surround the sub-pixel to define the sub-pixel (or the light-emitting area of each sub-pixel). Specifically, the fence F may overlap a portion of the edge area of the first electrode 132 to partition each sub-pixel, so that the potential mixing of lights of different colors output from adjacent sub-pixels may be prevented or suppressed.

The fence F may be made of an inorganic material, such as SiOx or SiNx, but is not limited thereto.

The light emitting layer 134 may be formed in R, G, and B sub-pixels and include an R-light emitting layer for emitting red light, a G-light emitting layer for emitting green light, and a B-light emitting layer for emitting blue light. Alternatively, the light emitting layer 134 may include a light emitting layer commonly disposed in each sub-pixel for emitting one color, for example, in example embodiments where color filters are employed. Also, for example, the light emitting layer 134 may be an organic light emitting layer, an inorganic light emitting layer, a nano-sized material layer, a quantum dot layer, a micro LED light emitting layer, or a mini LED light emitting layer, but is not limited thereto.

The light emitting layer 134 may include an emission layer, an electron injecting layer for injecting electrons into the emission layer, a hole injecting layer for injecting holes into the emission layer, an electron transporting layer for transporting the injected electrons to the emission layer, a hole transporting layer for transporting the injected holes to the emission layer, an electron blocking layer, and a hole blocking layer, but is not limited thereto.

The second electrode 136 is disposed on the light emitting layer 134. Where the display apparatus 100 according to example embodiments of the present disclosure is of the top emission type display apparatus, the second electrode 136 may be made of a half-transparent conductive material that transmits the light. For example, the second electrode 136 may be made of at least one of alloys such as LiF/Al, CsF/Al, Mg:Ag, Ca/Ag, LiF/Ca/Ag, and LiF/Ca:Ag. Alternatively, the second electrode 136 may be made of a transparent metal oxide, such as indium tin oxide (ITO) or indium zinc oxide (IZO), but is not limited thereto.

Further, the light emitting device D may be formed in a tandem structure. The tandem structure may include a plurality of organic light emitting layers (e.g., 134) and a charge generating layer disposed between the organic light emitting layers. The charge generating layer may be disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of an organic layer doped with an alkali metal, such as Li, Na, K, or Cs, or an alkaline earth metal, such as Mg, Sr, Ba, or Ra, but is not limited thereto.

A shielding electrode 164 is formed on the fence F. The shielding electrode 164 is formed to surround sub-pixels. The shielding electrode 164 may be formed of a single layer or a plurality of layers made of any one of molybdenum (Mo), aluminum (Al), chromium (Cr), gold (Au), titanium (Ti), nickel (Ni), neodymium (Nd), and copper (Cu), but is not limited thereto.

The connection electrode 162 is formed on the planarization layer 150. Although the connection electrode 162 may be made of the same material as the first electrode 132 of the light emitting device D by the same process, the connection electrode 162 is disposed to be spaced apart from the first electrode 132 by a predetermined distance, so that the connection electrode 162 is electrically insulated from the first electrode 132.

The connection electrode 162 is electrically connected to the reflective layer 160 through the second contact hole H2 formed in the planarization layer 150, and is electrically connected to the shielding electrode 164 through a third contact hole H3 formed in the fence F. That is, the shielding electrode 164 and the reflective layer 160 are electrically connected by the connection electrode 162.

Although not shown in the drawings, the reflective layer 160 may be connected to an external power supply to apply the low potential voltage thereto, and the low potential voltage may be supplied to the shielding electrode 164 through the connection electrode 162.

An encapsulation layer 180 is formed over the light emitting device D to encapsulate the light emitting device D. When the light emitting device D is exposed to external impurities such as moisture or oxygen, a pixel shrinkage phenomenon may occur in which the light emitting area is reduced or such defect as a dark spot appears in the light emitting area. Further, moisture or oxygen penetrating the light emitting device D may oxidize the metal electrode. The encapsulation layer 180 can block external impurities such as oxygen and moisture to prevent or suppress potential defects in the light emitting device D and various electrodes.

The encapsulation layer 180 may be formed of a first encapsulation layers 182, a second encapsulation layer 184, and a third encapsulation layer 186, but is not limited thereto. The encapsulation layer 180 may be formed of two layers or four or more layers.

The first encapsulation layer 182 and the third encapsulation layer 186 may be made of a single layer or multiple layers including inorganic materials, such as SiOx, SiON, SiNx, etc., and may further include organic materials between the inorganic materials, such as SiOx, SiON, SiNx, etc., but are not limited thereto. The second encapsulation layer 184 may be made of epoxy resin.

As described above, in example embodiments of the present disclosure, the shielding electrode 164 is disposed on the fence F, and the low potential voltage is supplied to the shielding electrode 164 through the reflective layer 160 and the connection electrode 162. This aspect of the present disclosure will be described in detail below.

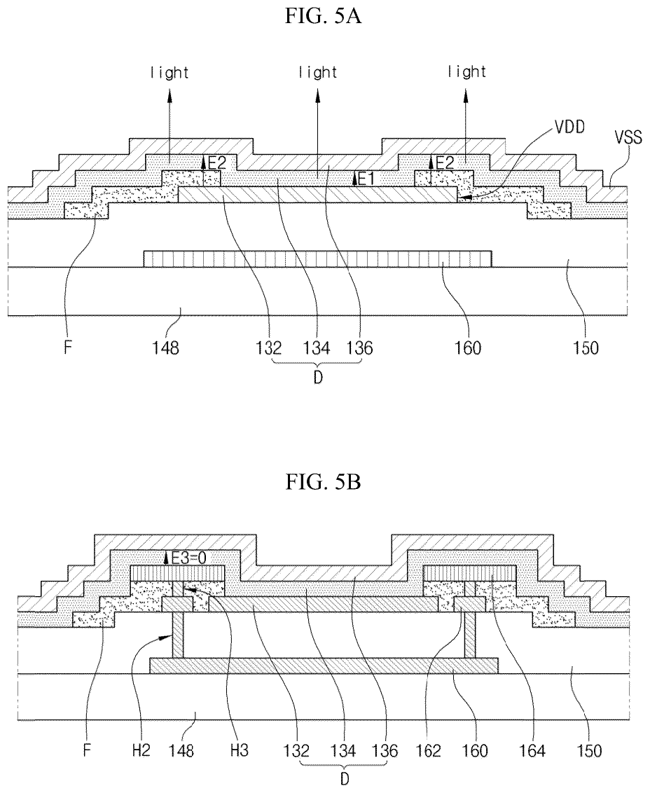

FIG. 5A is a cross-sectional view schematically illustrating a portion of an example sub-pixel of a display apparatus having the structure in which the shielding electrode is not formed. FIG. 5B is a cross-sectional view schematically illustrating a portion of an example sub-pixel of a display apparatus 100 according to an example embodiment of the present disclosure in which the shielding electrode 164 is formed. Here, for convenience of description, only the light emitting device D and the reflective layer 160 below the light emitting device D are shown, and the transistor T is not illustrated.

As shown in FIG. 5A, in the case of the display apparatus in which the shielding electrode is not formed, the high potential voltage VDD is applied to the first electrode 132 and the low potential voltage VSS is applied to the second electrode 136. Thus, an electric field E1 corresponding to the voltage difference (VDD-VSS) is formed between the first electrode 132 and the second electrode 136.

Due to the electric field E1, the light emitting layer 134 emits light and outputs the light to the outside. If the light emitting layer 134 in the boundary region of the sub-pixel also emits the light, the lights of different colors output from adjacent sub-pixels may be mixed and output to the outside. To prevent or suppress this, the fence F is formed in the boundary region of each sub-pixel. The fence F is disposed between the first electrode 132 and the second electrode 136 to block the electric field E1 therebetween so that the light emitting layer 134 does not emit light in the boundary region.

In recent years, to manufacture high-resolution display apparatuses, a display apparatus having a minimized or reduced interval between sub-pixels has been manufactured. However, in this case, as the distance between the adjacent sub-pixels decreases, the lateral leakage current is more likely to be generated between the adjacent sub-pixels. Since the lateral leakage current mainly flows to the adjacent sub-pixels through the light emitting layer 134, an electric field E2 may be generated due to the lateral leakage current in the light emitting layer 134 of the region where the fence F is disposed.

The intensity of the electric field E2 of the region in which the fence F is disposed is less than that of the electric field E1 of another region (E1>E2). However, since the light emitting layer 134 emits light even due to the small intensity electric field E2, the light may be output to the outside even in the region in which the fence F is disposed. Therefore, the light of different colors output from adjacent sub-pixels may be mixed, and thus the image quality may be deteriorated.

As shown in FIG. 5B, in the display apparatus 100 according to example embodiments of the present disclosure, the shielding electrode 164 is formed on the fence F. A voltage is applied to the shielding electrode 164 to increase an effect of shielding an electric field. The low potential voltage VSS applied to the second electrode 136 may be applied to the shielding electrode 164. For example, when an anode voltage of about 8 V is applied to the first electrode 132 and a cathode voltage of about 0 V is applied to the second electrode 136, an electric field is not generated in the light emitting layer 134 above the fence F (that is, E3=0), so the light emitting layer in this area does not emit light.

The same applies to the case where the organic light emitting device D has the tandem structure. The tandem structure includes a plurality of light emitting layers and a charge generation layer disposed between the light emitting layers. For example, when the anode voltage of about 8 V is applied to the first electrode 132 and the cathode voltage of 0 V is applied to the second electrode 136, the voltage of about 4 V is generated in the charge generation layer formed on the light emitting layer 134, and thus the light emitting layer disposed above and below the charge generation layer on the fence F emits the light. However, when the shielding voltage of 0 V is applied to the shielding electrode 164, the voltage of less intensity than the threshold voltage of the light emitting layer is applied to the charge generation layer, so the light emitting layer in this area does not emit light.

Therefore, since the light emitting layer 134 above the shielding electrode 164 does not emit the light, it is possible to prevent or suppress image quality deterioration due to mixing of different colors of light output from adjacent sub-pixels.

As described above, in the display apparatus 100 according to example embodiments of the present disclosure, since the shielding electrode 164 capable of maintaining the same potential as that of the second electrode 136 of the light emitting device D is disposed on the fence F, it is possible to prevent or suppress the light emission of the light emitting layer at the boundary of the sub-pixels even when the lateral leakage current flows in from the adjacent sub-pixel. Thus, it is possible to prevent or suppress mixing of lights of different colors output from adjacent sub-pixels.

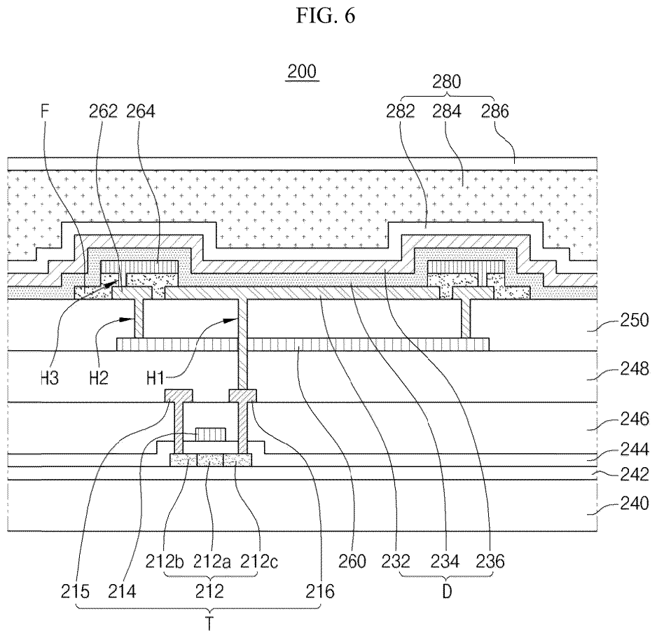

FIG. 6 is the cross-sectional view illustrating a partial structure of an example sub-pixel in the display apparatus 200 according to the second example embodiment of the present disclosure. The display apparatus 200 according to the second example embodiment of the present embodiment is not formed on the single crystal silicon wafer, but is formed on a substrate including a material such as glass or plastic. In this case, the same structure as that of the display apparatus 100 according to the first example embodiment of FIG. 4 is omitted or simplified, and only other structures are described in detail.

As shown in FIG. 6, the buffer layer 242 is formed on the substrate 240, and the transistor T and the light emitting device D are disposed on the buffer layer 242. The substrate 240 may be made of a hard material such as a glass or a flexible plastic material. Where the substrate 240 is formed of a plastic-based material, the substrate 240 may be formed of at least one of polyimide, polymethylmethacrylate, polyethylene terephthalate, polyethersulfone, and polycarbonate, but is not limited thereto.

Where the substrate 240 is made of polyimide, the substrate 240 may be made of a plurality of polyimide layers, and an inorganic layer may be further disposed between the polyimide layers, but embodiments of the present disclosure are not limited thereto.

The buffer layer 242 may be a single layer made of silicon oxide (SiOx) or silicon nitride (SiNx), or may include multiple layers of silicon oxide (SiOx) and/or silicon nitride (SiNx). Where the buffer layer 242 is made of multiple layers, SiOx and SiNx may be alternately formed. The buffer layer 242 may be omitted based on the type and material of the substrate 240, the structure and type of the thin film transistor T, and the like.

The transistor T includes the semiconductor layer 212 disposed on the buffer layer 242, the gate electrode 214 disposed on the gate insulating layer 244, and the source electrode 215 and the drain electrode 216 disposed on the interlayer insulating layer 246. The semiconductor layer 212 may include a channel region 212a that is not doped with impurities, and a source region 212b and a drain region 212c that are disposed respectively at two opposing sides of the channel region 212a and doped with impurities. The source electrode 215 and the drain electrode 216 may respectively contact the source region 212b and the drain region 212c of the semiconductor layer 212 through respective contact holes formed in the gate insulating layer 244 and the interlayer insulating layer 246.

The passivation layer 248 is formed on the transistor T, the reflective layer 260 is disposed on the passivation layer 248, and the planarization layer 250 is formed on the reflective layer 260.

The light emitting device D is disposed on the planarization layer 250. The light emitting device D includes a first electrode 232, a light emitting layer 234, and a second electrode 236.

The connection electrode 262 is formed on the planarization layer 250. The first electrode 232 and the connection electrode 262 are spaced apart from each other by a predetermined distance and are electrically insulated from each other. The first electrode 232 is electrically connected to the drain electrode 216 of the transistor T through the first contact hole H1 formed in the passivation layer 248 and the planarization layer 250 (in an area where the reflective layer 260 is not formed), and the connection electrode 262 is electrically connected to the reflective layer 260 through the contact hole H2 formed in the planarization layer 250.

The fence F is formed on the edge region of the first electrode 232. The fence F is formed along the edge of the first electrode 232 to surround the sub-pixel to define the sub-pixel (or the light emitting area of the sub-pixel). Specifically, since the fence F is formed to overlap the edge region of the first electrode 232 to partition each sub-pixel, the lights of different colors output from adjacent sub-pixels are not mixed. The fence F may be made of an inorganic material, such as SiOx or SiNx, but is not limited thereto.

The shielding electrode 264 is disposed on the fence F. The shielding electrode 264 may be made of a metal having high conductivity. The shielding electrode 264 is electrically connected to the connection electrode 262 through a third contact hole H3 formed in the fence F. Accordingly, an external power supply voltage, for example, the low potential voltage VSS, may be applied to the shielding electrode 264 through the reflective layer 260 and the connection electrode 262.

Since the shielding electrode 264 and the second electrode 236 over the fence F have the same electric potential, an electric field is not generated in the light emitting layer 234 over the fence F. Therefore, even when a lateral leakage current is introduced from the adjacent sub-pixel, the light emitting layer 234 in this edge region does not emit light. Thus, the lights of different colors output from the adjacent sub-pixels are not mixed.

As described above, the present disclosure can be applied to both the display apparatus 100 of example embodiments using a wafer substrate and the display apparatus 200 of example embodiments using a substrate made of glass or plastic.

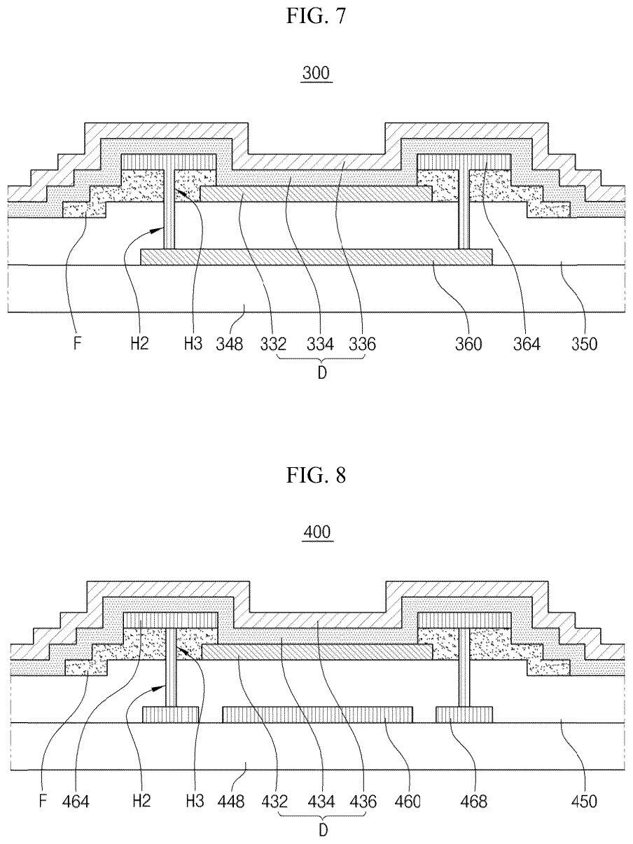

FIG. 7 is a cross-sectional view illustrating a portion of a sub-pixel in the display apparatus 300 according to a third embodiment of the present disclosure. In the display apparatus 300 of this example embodiment, a wafer substrate may be applied, or a glass or plastic substrate may be applied. Further, the display apparatus 300 of this example embodiment differs from the display apparatuses of the first and second example embodiments only in the structures of the reflective layer 360, the fence F, and the shielding electrode 364. Thus, details of the other structures may be omitted or simplified, and only the structures having differences will be described in detail.

As shown in FIG. 7, in the display apparatus 300 according to this example embodiment, the first electrode 332 of the light emitting device D is disposed on the planarization layer 350 and the fence F is disposed along the outer periphery of the first electrode 332 to overlap the edge region of the first electrode 332.

The shielding electrode 364 is disposed on the fence F. The shielding electrode 364 is directly connected to the reflective layer 360 through the contact hole H2 formed in the planarization layer 350 and the contact hole H3 formed in the fence F, and the voltage from the outside, for example, the low potential voltage, is directly applied to the shielding electrode 364 through the reflective layer 360. Here, the contact holes H2 and H3 may be aligned to form one continuous contact hole through the planarization layer 350 and the fence F.

In the display apparatus 100 according to the first example embodiment and the display apparatus 200 according to the second example embodiment of the present disclosure, the shielding electrode and the reflective layer are connected through the connection electrode (162 or 262), but in the display apparatus 300 according to this example embodiment, the shielding electrode 364 is directly connected to the reflective layer 360, so that a connection electrode is not necessary.

FIG. 8 is a cross-sectional view illustrating a portion of a sub-pixel in the display apparatus 400 according to a fourth example embodiment of the present disclosure. In the display apparatus 400 of this example embodiment, a wafer substrate may be applied, or a glass or plastic substrate may be applied. Further, the display apparatus 400 of this example embodiment differs from the display apparatus of the first and second example embodiments only in the structures of the reflective layer 460, the fence F, and the shielding electrode 464. Thus, details of the other structures may be omitted or simplified, and only these structures with differences will be described in detail.

As shown in FIG. 8, in the display apparatus 400 according to the fourth example embodiment of the present embodiment, the reflective layer 460 and the power supply electrode 468 are disposed on the passivation layer 448. A power supply voltage is supplied from the outside to the power supply electrode 468. For example, the power supply voltage may be the low potential voltage but is not limited thereto.

The reflective layer 460 improves the efficiency of the light output from the light emitting device D by microcavity effect of light. Since the power supply electrode 468 is disposed to be spaced apart from the reflective layer 460 by a predetermined distance, the reflective layer 460 and the power supply electrode 468 are electrically insulated from each other.

The power supply electrode 468 may be made of the same metal on the same underlying layer as the reflective layer 460 but is not limited thereto. For example, the power supply electrode 468 may be made of the different metal from the reflective layer 460 and/or be formed on a different underlying layer from a layer on which the reflective layer 460 is formed.

The first electrode 432 of the light emitting device D is disposed on the planarization layer 450, and the fence F is disposed along the outer periphery of the first electrode 432 to overlap the edge region of the first electrode 432.

The shielding electrode 464 is disposed on the fence F. The shielding electrode 464 is electrically connected to the power supply electrode 468 through the contact hole H2 formed in the planarization layer 450 and the contact hole H3 formed in the fence F to be supplied with a voltage, for example, the low potential voltage from the outside. Here, the contact holes H2 and H3 may be aligned to form one continuous contact hole through the planarization layer 350 and the fence F.

In the first to third example embodiments, the shielding electrode is electrically connected to the reflective layer (160, 260, or 360) to supply a voltage (e.g., the low potential voltage VSS) to the shielding electrode, whereas the display apparatus 400 of this example embodiment has the separate power supply electrode 468 to supply the low potential voltage VSS to the shielding electrode 464.

The above description of example embodiments and the accompanying drawings are merely illustrative of the technical spirit of the present disclosure. Those skilled in the art to which the present disclosure pertains can combine or modify example configurations within a range that does not depart from the features, aspects, or characteristics of the present disclosure, and various modifications or variations to the above example embodiments, such as separation, substitution, and alteration, will be possible and apparent to those skilled in the art. Therefore, the example embodiments of the present disclosure described above are not intended to limit the technical spirit of the present disclosure, and the scope of the technical spirit of the present disclosure is not limited by these example embodiments.

What is claimed is:

1. A display apparatus, comprising:
a substrate;
a light emitting device on the substrate and including a first electrode, a light emitting layer, and a second electrode;
a fence disposed along an outer periphery of the first electrode and covering an edge region of an upper surface of the first electrode; and
a shielding electrode on the fence and configured to receive a voltage.

2. The display apparatus of claim 1, wherein the shielding electrode and the second electrode are configured to receive the same voltage or have a same electric potential.

3. The display apparatus of claim 1, wherein the substrate includes one of a semiconductor wafer, a plastic material, and a glass.

4. The display apparatus of claim 1, further comprising:
a transistor on the substrate; and
a passivation layer covering the transistor,
wherein the transistor is electrically connected to the first electrode through a first contact hole in the passivation layer.

5. The display apparatus of claim 4, further comprising:
a reflective layer on the passivation layer; and
a planarization layer covering the reflective layer, the light emitting device being disposed on the planarization layer.

6. The display apparatus of claim 5, wherein the shielding electrode is electrically connected to the reflective layer through a second contact hole in the planarization layer and a third contact hole in the fence.

7. The display apparatus of claim 6, further comprising:
a connection electrode on the planarization layer,
wherein the connection electrode is electrically connected to the shielding electrode through the third contact hole in the fence and to the reflective layer through the second contact hole in the planarization layer.

8. The display apparatus of claim 7, wherein the connection electrode includes a same material as the first electrode and is insulated from the first electrode.

9. The display apparatus of claim 6, wherein:
the voltage is a power supply voltage; and
the shielding electrode is configured to receive the power supply voltage through the reflective layer.

10. The display apparatus of claim 9, wherein the power supply voltage is a low potential voltage.

11. The display apparatus of claim 6, wherein:
the shielding electrode is connected directly to the reflective layer through the second contact hole and the third contact hole; and
the second contact hole and the third contact hole are aligned to form a continuous contact hole through the planarization layer and the fence.

12. The display apparatus of claim 5, further comprising:
a power supply electrode on the passivation layer and electrically connected to the shielding electrode to supply the voltage to the shielding electrode,
wherein the voltage is a power supply voltage.

13. The display apparatus of claim 12, wherein the power supply electrode is electrically connected to the shielding electrode through a second contact hole in the planarization layer and a third contact hole in the fence.

14. The display apparatus of claim 13, wherein:
the shielding electrode is connected directly to the power supply electrode through the second contact hole and the third contact hole; and
the second contact hole and the third contact hole are aligned to form a continuous contact hole through the planarization layer and the fence.

15. The display apparatus of claim 12, wherein the power supply electrode includes a same material as the reflective layer and is insulated from the reflective layer.

16. The display apparatus of claim 1, wherein:
the shielding electrode overlaps the edge region of the upper surface of the first electrode; and
the fence includes an insulating material and is disposed between the shielding electrode and the edge region of the upper surface of the first electrode.

17. The display apparatus of claim 16, wherein:
the light emitting layer is disposed on the shielding electrode and the first electrode; and
the second electrode is disposed on the light emitting layer, the second electrode overlapping the shielding electrode.

18. A display apparatus, comprising:
a substrate;
a transistor on the substrate;
a light emitting device over the transistor and including a first electrode electrically connected to the transistor, a light emitting layer, and a second electrode;
a fence disposed along an outer periphery of the first electrode and overlapping an edge region of the first electrode, the fence including an insulating material; and
a shielding electrode on the fence and overlapping the edge region of the first electrode, the fence being disposed between the shielding electrode and the edge region of the first electrode,
wherein the light emitting layer is disposed on the shielding electrode and the first electrode, and the second electrode is disposed on the light emitting layer and overlaps the shielding electrode, and
wherein the shielding electrode and the second electrode are configured to receive a same power supply voltage or be at a same electric potential.

19. The display apparatus of claim 18, further comprising:
a reflective layer between the transistor and the first electrode of the light emitting device,
wherein the shielding electrode is electrically connected to the reflective layer and is configured to receive the power supply voltage through the reflective layer.

20. The display apparatus of claim 18, further comprising:
a passivation layer on the transistor;
a reflective layer on the passivation layer and under the first electrode of the light emitting device; and
a power supply electrode on the passivation layer and electrically insulated from the reflective layer,
wherein the shielding electrode is electrically connected to the power supply electrode and is configured to receive the power supply voltage through the power supply electrode.
